(19) United States
(12) Patent Application Publication
(10) Pub. No.: US 2013/0186850 A1
(43) Pub. Date: Jul. 25, 2013

(54) SLURRY FOR COBALT APPLICATIONS

(71) Applicants: You Wang, Cupertino, CA (US); Chenhao Ge, San Jose, CA (US); Yufei Chen, Cupertino, CA (US); Yuchun Wang, Santa Clara, CA (US); Wen-Chiang Tu, Mountain View, CA (US); Lakshmanan Karuppiah, San Jose, CA (US)

(72) Inventors: You Wang, Cupertino, CA (US); Chenhao Ge, San Jose, CA (US); Yufei Chen, Cupertino, CA (US); Yuchun Wang, Santa Clara, CA (US); Wen-Chiang Tu, Mountain View, CA (US); Lakshmanan Karuppiah, San Jose, CA (US)

(73) Assignee: Applied Materials, Inc.

(21) Appl. No.: 13/357,535

(22) Filed: Jan. 24, 2012

(51) Int. Cl. C09K 13/00; C09K 13/02; H05K 3/26

(52) U.S. Cl. 216/13; 252/79.1; 252/79.5

(57) ABSTRACT

A slurry for chemical mechanical of a cobalt layer or a conductive layer over a cobalt layer includes abrasive particles, an organic complexing compound for Cu or Co ion complexion, a Co corrosion inhibitor that is 0.01-1.0 wt % of the slurry, an oxidizer, and a solvent. The slurry has a pH of 7-12.

### TECHNICAL FIELD

The present invention relates generally to chemical mechanical polishing of substrates.

### BACKGROUND

In the process of fabricating modern semiconductor integrated circuits (IC), it is often necessary to planarize the outer surface of the substrate. For example, planarization may be needed to polish away a conductive filler layer until the top surface of an underlying dielectric layer is exposed, leaving the conductive material between the raised pattern of the dielectric layer to form vias, plugs and lines that provide conductive paths between thin film circuits on the substrate. A barrier layer can be disposed between the dielectric layer and the conductive filler layer.

Chemical mechanical polishing (CMP) is one accepted method of planarization. This planarization method typically requires that a substrate be mounted on a carrier head. The exposed surface of the substrate is typically placed against a rotating polishing pad. The polishing pad can have a durable roughened surface. An abrasive polishing slurry is typically supplied to the surface of the polishing pad. The carrier head provides a controllable load on the substrate to push it against the polishing pad while the substrate and polishing pad undergo relative motion.

### SUMMARY

Cobalt (Co) has been proposed as a material for the barrier layer between the underlying patterned dielectric layer, e.g., silicon oxide or a low-k material, and a conductive filler layer, e.g., copper (Cu). One step in device fabrication is polishing of the conductive layer until either the underlying barrier layer or the underlying dielectric layer is exposed. Unfortunately, existing slurries for polishing of copper do not appear to give satisfactory CMP performance when the barrier layer is cobalt. Without being limited to any particular theory, cobalt is chemically reactive with copper polishing slurries, resulting in cobalt dissolution, which in turn leads to a high defect count. However, new slurry formulations, e.g., with proper selection of a cobalt corrosion inhibitor, may be able to provide satisfactory performance, such as high removal rate and low defects.

Cobalt (Co) has also been proposed as a material for the conductive layer itself As mentioned above, one step in device fabrication is polishing of the conductive layer until either the underlying barrier layer or the underlying dielectric layer is exposed. Unfortunately, existing slurries for polishing of cobalt do not appear to give satisfactory CMP performance. Again, without being limited to any particular theory, this may be due to cobalt being chemically reactive with the existing slurries. However, proper selection of a cobalt corrosion inhibitor can significantly reduce defects.

In one aspect a slurry for chemical mechanical of a cobalt layer or a conductive layer over a cobalt layer includes abrasive particles, an organic complexing compound for Cu or Co ion complexion, a Co corrosion inhibitor that is 0.01-1.0 wt % of the slurry, an oxidizer, and a solvent. The slurry has a pH of 7-12.

Implementations may include one or more of the following. The abrasive particles may be alumina oxide. The organic complexing compound may include glycine, citric acid, acetic acid or carboxylic acid. The organic complexing compound may be 0.2-2.0 wt % of the slurry. The Co corrosion inhibitor may include an organic compound with an amine functional group. The Co corrosion inhibitor may include triazole, benzotriazole (BTA) or melamine. The Co corrosion inhibitor may be 1,2,4-Triazole, and the Cu corrosion inhibitor may be 0.015-0.02 wt % of the slurry, e.g., 0.016-0.018 wt % of the slurry. The oxidizer may include ammonium peroxide or hydrogen peroxide. The oxidizer may be ammonium peroxide, and the oxidizer may be 0.5-1.0 vol % of the slurry, e.g., 0.8-0.85 vol % of the slurry. The slurry may include a pH adjustor, e.g., KOH. The solvent may be water.

In another aspect, a method of polishing includes bringing a substrate having a conductive layer disposed over a cobalt barrier layer into contact with a polishing pad, supplying a slurry to the polishing pad, and generating relative motion between the substrate and the polishing pad to polish the conductive layer until at least the cobalt barrier layer is exposed. The slurry includes abrasive particles, an organic complexing compound for Cu or Co ion complexion, a Co corrosion inhibitor that is 0.01-1.0 wt % of the slurry, an oxidizer, a solvent, and a pH adjustor at a concentration to provide a pH of 7-12.

Implementations may include one or more of the following. The Co corrosion inhibitor may be 1,2,4-triazole and the Cu corrosion inhibitor may be about 0.018 wt % of the slurry. The oxidizer may be ammonium peroxide and the oxidizer may be 0.85 vol % of the slurry.

In another aspect, a method of polishing includes bringing a substrate having a cobalt conductive layer disposed over an underlying layer into contact with a polishing pad, supplying a slurry to the polishing pad, and generating relative motion between the substrate and the polishing pad to polish the cobalt conductive layer until the underlying layer is exposed. The slurry includes abrasive particles, an organic complexing compound for Cu or Co ion complexion, a Co corrosion inhibitor that is 0.01-1.0 wt % of the slurry, an oxidizer and a solvent. The slurry has a pH of 7-12.

Implementations may include one or more of the following. The Co corrosion inhibitor may be 1,2,4-triazole and the Cu corrosion inhibitor may be 0.016 wt % of the slurry. The oxidizer may be ammonium peroxide and the oxidizer may be 0.80 vol % of the slurry.

Advantages may include optionally one or more of the following. A copper conductive layer can be polished until an underlying cobalt barrier layer is exposed with a low defect count and while maintaining satisfactory polishing rate and polishing uniformity. For example, the post barrier polishing defect count can be less than 100 by SP2 measurement, the polishing rate can be about 2000 Å/min, and within-wafer non-uniformity can be 2%. A copper bulk conductive layer can be polished under an underlying barrier layer is exposed with a low dishing and while maintaining satisfactory polishing rate.

### BRIEF DESCRIPTION OF DRAWINGS

FIGS. 1A and 1B illustrate polishing of a substrate having a conductive layer over a patterned dielectric layer.

### DETAILED DESCRIPTION

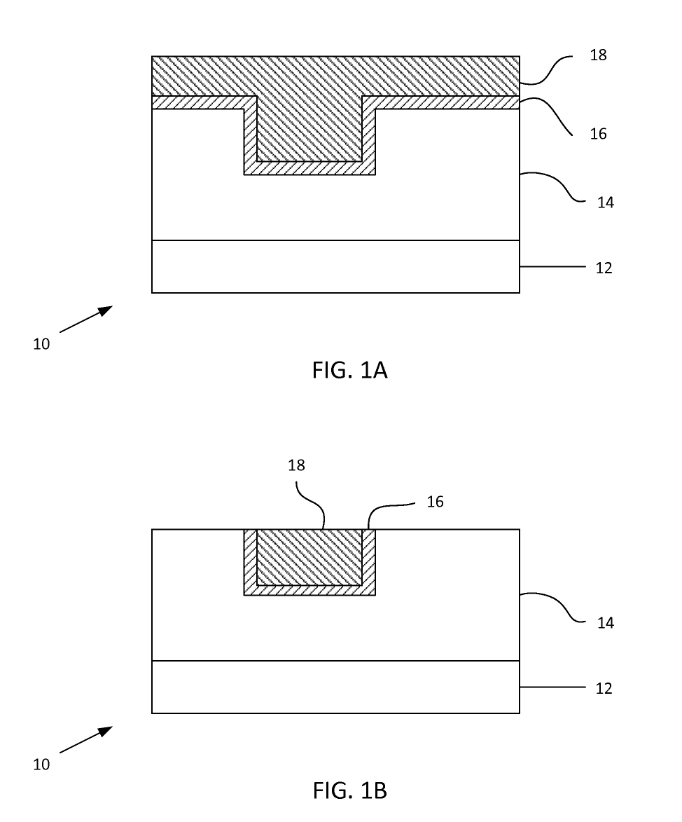

Referring to FIG. 1A, during an integrated circuit fabrication process, a substrate 10 can include a glass or semiconductor substrate 12, a patterned dielectric layer 14, and a conductive layer 18 disposed over the dielectric layer 14. A barrier layer 16 can be disposed between the dielectric layer 14 and the conductive layer 18. Additional unillustrated conductive and/or dielectric layers can be formed between the substrate 12 and the dielectric layer 14. The dielectric layer 14 can be an oxide, e.g., silicon oxide, or a low-k dielectric, e.g., a porous carbon-doped oxide. At least one of the barrier layer 16 or the conductive layer 18 is cobalt. For example, the conductive layer 18 can be a metallic layer other than cobalt, e.g., copper, and the barrier layer 16 can be cobalt. Alternatively, the conductive layer 18 can be cobalt, and the barrier layer 16 could be omitted, although a cobalt layer deposited by CVD could be used as a seed layer.

As noted above, commercial slurries for polishing of copper do not give satisfactory performance when a cobalt barrier layer is present, and commercial slurries for polishing of cobalt similarly do not give satisfactory CMP performance.

A proposed slurry chemistry that might potentially address these problems can include (1) abrasive particles, (2) an organic complexing compound for metal ion complexion, (3) a Co corrosion inhibitor, and (4) a solvent such as water.

Typically, the range for the chemical components in the slurry is given below in Table 1.

TABLE 1

| | |
|---|---|
| Abrasive particles | 0.1-10 wt % |
| Organic complexing compound | 0.2-2.0 wt % |
| Co corrosion inhibitor | 0.01-1.0 wt % |

The abrasive particles can be an oxide, such as fumed or colloidal aluminum oxide (Al₂O₃) or silica oxide (SiO₂). The size of the abrasive particles can be in a range of 20 nm-100 nm. For example, the abrasive particles can be those from C7092 from Cabot.

The organic complexing compound is a substance capable of forming a complex compound with metal ions, e.g., Cu or Co ions. Thus, molecules or ions of a nonmetal (the complexing compound) form coordinate bonds with the Cu or Co ions. The organic complexing compound can be glycine. However, other organic acids, such as citric acid, acetic acid or carboxylic acids can be used.

The Co corrosion inhibitor can be an organic compound with an amine functional group, such as triazole, benzotriazole (BTA) or melamine. In particular, the Co corrosion inhibitor can be 1,2,4-Triazole with a concentration of 0.01-1.0 wt %, e.g., 0.01-0.1 wt %.

The slurry can also include an oxidizer. For example, the oxidizer can be ammonium persulfate (APS) and/or hydrogen peroxide. The oxidizer can be present in a concentration of 0.5-1.0 vol % of the slurry, e.g., 0.8-0.85 vol % of the slurry.

The slurry can also include a Cu corrosion inhibitor, e.g., a corrosion inhibitor of different composition than the Co corrosion inhibitor, e.g., not 1,2,4-Triazole.

The pH of the slurry may be in the range of 7-12, e.g., 8-9. If necessary, the slurry can also include a pH adjustor to set the pH of the slurry. The pH adjustor can be KOH.

### EXAMPLE 1

Bulk polishing of a copper conductive layer over a cobalt barrier layer can be conducted, e.g., at platen 1 and platen 2 of a Mirra™ or Reflexion™ polishing system. Bulk polishing can be conducted at a relatively a pressure of 1.5 to 2.5 psi, e.g., 2.1 psi, and at a platen rotation rate of 73-113 rpm.

Slurry for the polishing can be provided by modifying a C7092 Cabot slurry by 1:2.5 dilution with water, and by adding the following components:

1,2,4 triazole 0.018 wt %

H₂O₂ 0.85 wt %

pH: 8.5, adjusted by KOH

It may be noted that C7092 Cabot slurry includes Cu corrosion inhibitor.

Bulk polishing and copper clearing can be followed by oxide polishing step, e.g., at platen 3, using a soft pad, e.g., a Fujibo pad, and a commercial oxide slurry such as 6618-12A or LK393 from Cabot, at pressure of about 1.5 psi or less.

Oxide polishing can be followed by a cleaning step using a diluted commercially available alkaline solution.

### EXAMPLE 2

Bulk polishing and clearing of a cobalt conductive layer over a dielectric layer can be conducted, e.g., at platen 1 and platen 2 of a Mirra™ or Reflexion™ polishing system. Polishing can be performed using a microporous polyurethane pad, e.g., an IC-1010 polishing pad from Dow. Polishing can be conducted at a relatively low pressure, e.g., 1.0 to 1.5 psi, and at a platen rotation rate of 73-113 rpm.

Slurry for the polishing can be provided by modifying a C7092 Cabot slurry by adding the following components:

1,2,4 triazole 0.016 wt %

H₂O₂ 0.80 wt %

The resulting slurry can have a pH of 8.5; no pH adjustor is required.

Bulk polishing can be followed by buffing step, e.g., at platen 3, using a soft buffing pad, e.g., a EV4000 pad, and a commercial barrier slurry such as LK393, B8755 at pressure of about 1.0 psi or less.

Buffing can be followed by a cleaning step using a diluted commercially available alkaline solution.

In general, providing an appropriate concentration of a Co corrosion inhibitor significantly reduce polishing defects during polishing of a copper conductive layer over a cobalt barrier layer or polishing of a cobalt conductive layer.

What is claimed is:

1. A slurry for chemical mechanical polishing of a cobalt layer or a conductive layer over a cobalt layer, comprising:
abrasive particles;
an organic complexing compound for Cu or Co ion complexion;
a Co corrosion inhibitor that is 0.01-1.0 wt % of the slurry;
an oxidizer; and
a solvent; and
wherein the slurry has a pH of 7-12.

2. The slurry of claim 1, wherein the abrasive particles comprise alumina oxide.

3. The slurry of claim 1, wherein the organic complexing compound comprises glycine, citric acid, acetic acid or carboxylic acid.

4. The slurry of claim 3, wherein the organic complexing compound is 0.2-2.0 wt % of the slurry.

5. The slurry of claim 1, wherein the Co corrosion inhibitor comprises an organic compound with an amine functional group.

6. The slurry of claim 5, wherein the Co corrosion inhibitor comprises triazole, benzotriazole (BTA) or melamine.

7. The slurry of claim 1, wherein the Co corrosion inhibitor comprises 1,2,4-Triazole.

8. The slurry of claim 7, wherein the Co corrosion inhibitor is 0.015-0.02 wt % of the slurry.

9. The slurry of claim 8, wherein the Co corrosion inhibitor is 0.016-0.018 wt % of the slurry.

10. The slurry of claim 1, wherein the oxidizer comprises ammonium peroxide or hydrogen peroxide.

11. The slurry of claim 1, wherein the oxidizer comprises ammonium peroxide.

12. The slurry of claim 11, wherein the oxidizer is 0.5-1.0 vol % of the slurry.

13. The slurry of claim 12, wherein the oxidizer is 0.8-0.85 vol % of the slurry.

14. The slurry of claim 1, further comprising a pH adjustor.

15. The slurry of claim 14, wherein the pH adjustor comprises KOH.

16. The slurry of claim 1, wherein the solvent is water.

17. A method of polishing, comprising:
bringing a substrate having a conductive layer disposed over a cobalt barrier layer into contact with a polishing pad;
supplying a slurry to the polishing pad, wherein the slurry includes abrasive particles, an organic complexing compound for Cu or Co ion complexion, a Co corrosion inhibitor that is 0.01-1.0 wt % of the slurry, an oxidizer, a solvent, and a pH adjustor at a concentration to provide a pH of 7-12; and
generating relative motion between the substrate and the polishing pad to polish the conductive layer until at least the cobalt barrier layer is exposed.

18. The method of claim 17, wherein the Co corrosion inhibitor comprises 1,2,4-triazole and the Co corrosion inhibitor is 0.018 wt % of the slurry.

19. The method of claim 18, wherein the oxidizer comprises ammonium peroxide and the oxidizer is 0.85 vol % of the slurry.

20. A method of polishing, comprising:
bringing a substrate having a cobalt conductive layer disposed over an underlying layer into contact with a polishing pad;
supplying a slurry to the polishing pad, wherein the slurry includes abrasive particles, an organic complexing compound for Cu or Co ion complexion, a Co corrosion inhibitor that is 0.01-1.0 wt % of the slurry, an oxidizer and a solvent, wherein the slurry has a pH of 7-12; and
generating relative motion between the substrate and the polishing pad to polish the cobalt conductive layer until the underlying layer is exposed.

21. The method of claim 20, wherein the Co corrosion inhibitor comprises 1,2,4-triazole and the Co corrosion inhibitor is 0.016 wt % of the slurry.

22. The method of claim 21, wherein the oxidizer comprises ammonium peroxide and the oxidizer is 0.80 vol % of the slurry.
